(19) United States
(12) Patent Application Publication
(10) Pub. No.: US 2026/0101774 A1
(43) Pub. Date: Apr. 9, 2026

(54) SEMICONDUCTOR DEVICE AND MANUFACTURING METHOD THEREOF

(71) Applicant: Kioxia Corporation, Tokyo (JP)

(72) Inventor: Hideki TABARA, Kawasaki Kanagawa (JP)

(21) Appl. No.: 19/070,404

(22) Filed: Mar. 4, 2025

(30) Foreign Application Priority Data
Sep. 10, 2024 (JP) 2024-156790

(51) Int. Cl. H01L 23/00; H01L 23/538; H01L 25/07; H10B 80/00

(52) U.S. Cl. CPC H10W 70/60; H10W 70/611; H10W 90/00; H10B 80/00; H10W 72/07202; H10W 72/07236; H10W 72/281; H10W 90/724

(57) ABSTRACT

According to one embodiment, a semiconductor device includes a substrate, at least one semiconductor part, and a non-semiconductor part. The substrate has a first face and a second face on a side opposite to that of the first face, and has a first linear expansion coefficient. The at least one semiconductor part is disposed on a first region of the first face, and has a second linear expansion coefficient that is smaller than the first linear expansion coefficient. The non-semiconductor part is disposed on a second region of the first face, on which no semiconductor part is disposed, and has a third linear expansion coefficient that is greater than the first linear expansion coefficient.

### CROSS-REFERENCE TO RELATED APPLICATION(S)

This application is based upon and claims the benefit of priority from Japanese Patent Application No. 2024-156790, filed Sep. 10, 2024, the entire contents of which are incorporated herein by reference.

### FIELD

Embodiments described herein relate generally to a semiconductor device, and to a manufacturing method thereof.

### BACKGROUND

When manufacturing a semiconductor device such as a semiconductor storage device, there is a case where a semiconductor part is mounted on a substrate using reflow soldering. In such case, thermal warping of the substrate caused by the reflow soldering may occur.

### BRIEF DESCRIPTION OF THE DRAWINGS

FIG. 1 is a sectional view showing an example of a configuration of a semiconductor device according to an embodiment.

FIG. 2 is a perspective view showing an example of a configuration of the semiconductor device according to the embodiment.

FIG. 3 is a plan view showing an example of a configuration of the semiconductor device according to the embodiment.

FIGS. 4-6 are sectional views showing a method of manufacturing the semiconductor device according to the embodiment.

FIG. 7 is a plan view showing thermal warping of a substrate of the semiconductor device according to the embodiment.

FIG. 8 is a plan view showing the semiconductor device according to a first modification of the embodiment.

FIG. 9 is a sectional view showing the semiconductor device according to a second modification of the embodiment.

### DETAILED DESCRIPTION

Embodiments provide a semiconductor device, and a manufacturing method thereof, such that warping of a substrate can be reduced.

In general, according to one embodiment, a semiconductor device includes a substrate, at least one semiconductor part, and a non-semiconductor part. The substrate has a first face and a second face on a side opposite to that of the first face, and has a first linear expansion coefficient. The at least one semiconductor part is disposed on a first region of the first face, and has a second linear expansion coefficient that is smaller than the first linear expansion coefficient. The non-semiconductor part is disposed on a second region of the first face, on which no semiconductor part is disposed, and has a third linear expansion coefficient that is greater than the first linear expansion coefficient.

Hereafter, an embodiment will be described while referring to the drawings. In order to facilitate understanding of the description, identical reference signs will be allotted, as far as possible, to identical components in the drawings, and redundant descriptions will be omitted.

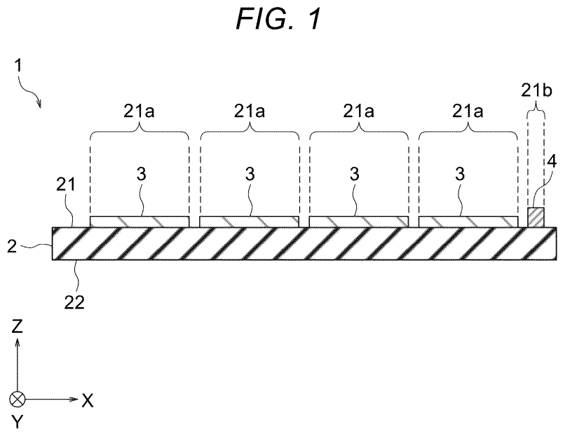

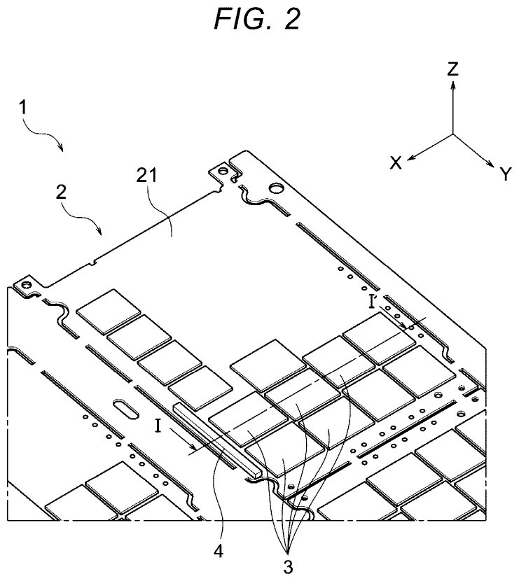

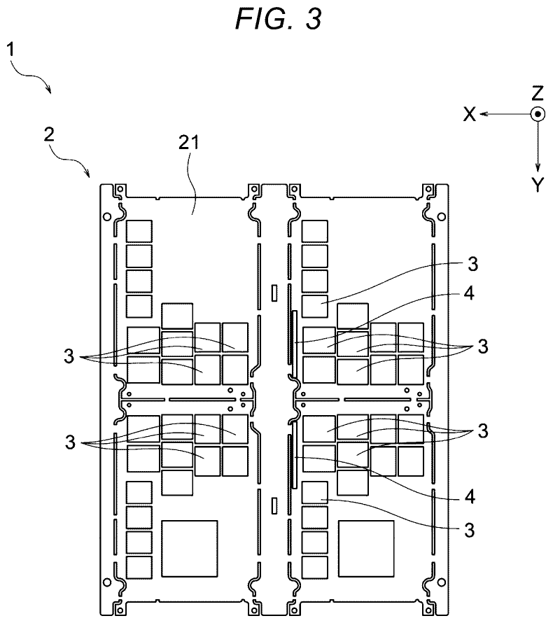

FIG. 1 is a sectional view showing an example of a configuration of a semiconductor device 1 according to an embodiment. FIG. 2 is a perspective view showing an example of a configuration of the semiconductor device 1 according to the embodiment. FIG. 1 corresponds to an I-I section of the semiconductor device shown in FIG. 2. FIG. 3 is a plan view showing an example of a configuration of the semiconductor device 1 according to the embodiment. FIG. 1 shows one portion of the semiconductor device 1 shown in FIGS. 2 and 3. The semiconductor device 1 shown in FIGS. 2 and 3 is divided into a plurality of portions, each of which can be mounted in a semiconductor storage device.

The semiconductor device 1 can, for example, be advantageously used in a semiconductor storage device, such as a large-scale solid-state drive (SSD), in which a plurality of semiconductor parts are mounted. As shown in FIGS. 1 to 3, the semiconductor device 1 includes a substrate 2, a plurality of semiconductor parts 3, and an additional part 4. The additional part 4 is one example of a first part.

As shown in FIG. 1, the substrate 2 has a first face 21, and a second face 22 positioned on a side opposite to that of the first face 21. As shown in FIG. 1, a direction following a thickness direction of the substrate 2 is defined as a Z direction. Also, a direction from the second face 22 toward the first face 21 is defined as an upward direction. A direction from the first face 21 toward the second face 22 is defined as a downward direction. The upward direction is a direction opposite to the downward direction. In this case, the first face 21 can also be called an upper face of the substrate 2. These expressions are for the sake of the description, and do not define a direction of gravitational force. Also, the second face 22 can also be called a lower face of the substrate 2. An X direction and a Y direction are directions parallel to the first face 21 of the substrate 2. The X direction is a direction that intersects (for example, is perpendicular to) the Y direction. The X direction and the Y direction are directions that intersect (for example, are perpendicular to) the Z direction. The X direction is one example of a first direction. The Y direction is one example of a second direction.

The substrate 2 has a first linear expansion coefficient. A linear expansion coefficient is also called a linear expansion rate. The first linear expansion coefficient is a ratio between an amount of change in length of the substrate 2 per 1° C. of change in temperature of the substrate 2 and an original length of the substrate 2. The first linear expansion coefficient can be expressed using, for example, the following equation [1].

$${α}_{1} = ( 1 / {L}_{1} ) \times ( {dL}_{1} / {dT}_{1} ) \qquad [ 1 ]$$

Here, α₁ is the first linear expansion coefficient. L₁ is an original length (for example, an X direction length) of the substrate 2. dL₁ is the amount of change in length of the substrate 2. dT₁ is the amount of change in temperature of the substrate 2.

The first linear expansion coefficient can be calculated based on, for example, a result of a simulation or an experiment measuring a change in the length of the substrate 2 in response to a change in temperature of the substrate 2.

In the example shown in FIG. 3, the substrate 2 has an approximately rectangular form when seen from the Z direction (that is, in plan view). The substrate 2, for example, contains a resin material, and is a wiring substrate on which wiring (not shown) is provided. The substrate 2 has a plurality of wiring layers. The substrate 2 may further include a via that connects wiring or an electrode on an upper layer side and wiring on a lower layer side. The first linear expansion coefficient is, for example, approximately 15 ppm/° C.

As shown in FIG. 1, the semiconductor part 3 is disposed on a first region 21a of the first face 21. The first region 21a is a region of the first face 21 on which the semiconductor part 3 is disposed. The first region 21a can also be called a mounting region of the semiconductor part 3. The plurality of semiconductor parts 3 are disposed neighboring in the X direction and the Y direction in FIGS. 1 to 3. The semiconductor part 3 has a second linear expansion coefficient smaller than the first linear expansion coefficient.

The second linear expansion coefficient is a ratio between an amount of change in length of the semiconductor part 3 per 1° C. of change in temperature of the semiconductor part 3 and an original length of the semiconductor part 3. The second linear expansion coefficient can be expressed using, for example, the following equation [2].

$${α}_{2} = ( 1 / {L}_{2} ) \times ( {dL}_{2} / {dT}_{2} ) \qquad [ 2 ]$$

Here, α₂ is the second linear expansion coefficient. L₂ is an original length (for example, an X direction length) of the semiconductor part 3. dL₂ is the amount of change in length of the semiconductor part 3. dT₂ is the amount of change in temperature of the semiconductor part 3.

The second linear expansion coefficient can be calculated based on, for example, a result of a simulation or an experiment measuring a change in the length of the semiconductor part 3 in response to a change in temperature of the semiconductor part 3.

The semiconductor part 3 is, for example, a NAND flash memory. A NAND flash memory has, for example, a wiring substrate on which a terminal such as a solder ball to be electrically connected to the substrate 2 is provided, at least one memory chip mounted on the wiring substrate, and a sealing resin that seals the memory chip. When the semiconductor part 3 is a NAND flash memory, the second linear expansion coefficient is, for example, approximately 3.5 ppm/° C.

The additional part 4 is a part additionally disposed on the substrate 2 in order to reduce thermal warping of the substrate 2 caused by a difference between the linear expansion coefficients of the semiconductor part 3 and the substrate 2. The additional part 4 is disposed on a second region 21b of the first face 21 on which the semiconductor part 3 is not disposed. The second region 21b can also be called a non-mounting region on which the semiconductor part 3 is not mounted. The second region 21b can also be called an empty space. The additional part 4 has a third linear expansion coefficient greater than the first linear expansion coefficient.

The third linear expansion coefficient is a ratio between an amount of change in length of the additional part 4 per 1° C. of change in temperature of the additional part 4 and an original length of the additional part 4. The third linear expansion coefficient can be expressed using, for example, the following equation [3].

$${α}_{3} = ( 1 / {L}_{3} ) \times ( {dL}_{3} / {dT}_{3} ) \qquad [ 3 ]$$

Here, α₃ is the third linear expansion coefficient. L₃ is an original length (for example, an X direction length) of the additional part 4. dL₃ is the amount of change in length of the additional part 4. dT₃ is the amount of change in temperature of the additional part 4.

The third linear expansion coefficient can be calculated based on, for example, a result of a simulation or an experiment measuring a change in the length of the additional part 4 in response to a change in temperature of the additional part 4.

The additional part 4 is a part excluding a semiconductor part, that is, a part other than a semiconductor part. In other words, the additional part 4 is a part that does not include a semiconductor as a component thereof. The additional part 4 can also be called a part that is not involved in electrical properties of the semiconductor device 1. The additional part 4 is not electrically connected to any wiring included in the substrate 2. The additional part 4 is provided on an insulating layer (for example, a solder resist layer) provided on the substrate 2. The additional part 4 is made of, for example, metal. The linear expansion coefficient of the additional part 4 is greater than the linear expansion coefficients of the substrate 2 and the semiconductor part 3. The metal of the additional part 4 is preferably aluminum. By using aluminum, the additional part 4 that has a large linear expansion coefficient can be formed at a low cost. When the additional part 4 is formed of aluminum, the third linear expansion coefficient is 23.9 ppm/° C. The additional part 4 may also be formed of copper.

As described above, when the first linear expansion coefficient is expressed using equation [1], the second linear expansion coefficient is expressed using equation [2], and the third linear expansion coefficient is expressed using equation [3], the following equation [4] is established among the three linear expansion coefficients.

$${α}_{2} < {α}_{1} < {α}_{3} \qquad [ 4 ]$$

In the example shown in FIG. 3, the additional part 4 is disposed in a vicinity of a center of the first face 21. That is, the additional part 4 is disposed in a vicinity of a central position in the X direction of the first face 21, and in a vicinity of a central position in the Y direction of the first face 21. In other words, the additional part 4 is disposed in a position nearer than the semiconductor part 3 to the center of the first face 21.

Two additional parts 4 are disposed across an interval in the Y direction on the first face 21 of the substrate 2. In the example shown in FIG. 3, a dimension of the additional part 4 in the X direction of the first face 21 is smaller than that of the semiconductor part 3. Specifically, the additional part 4 has a rod shape extending in the Y direction that intersects the X direction of the first face 21. Also, in the example shown in FIG. 3, a dimension of the additional part 4 in the Z direction is greater than that of the semiconductor part 3.

Also, in the example shown in FIG. 3, the additional part 4 extends in the Y direction to a length such as to oppose two or more semiconductor parts 3 in the X direction. That is, the additional part 4 extends in the Y direction in such a way as to straddle two or more semiconductor parts 3 when seen from the X direction.

The semiconductor part 3 is mechanically and electrically connected to the substrate 2 via a conductive layer (not shown) disposed on the first region 21a. For example, the semiconductor part 3 is electrically connected to the substrate 2 by being connected to an electrode provided on the substrate 2 across the conductive layer. The additional part 4 is mechanically connected to the substrate 2 across a conductive layer (not shown) disposed on the second region 21b. The additional part 4 is not electrically connected to wiring of the substrate 2. The conductive layer is, for example, a solder layer. That is, the semiconductor part 3 and the additional part 4 are connected onto the substrate 2 using conductive layers of the same material.

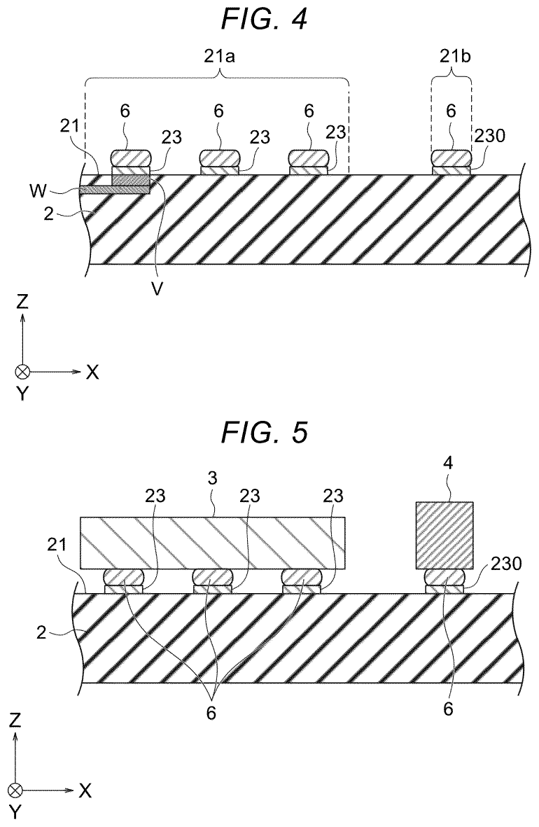

Next, a method of manufacturing the semiconductor device 1 having the heretofore described configuration will be described. FIG. 4 is a sectional view showing a method of manufacturing the semiconductor device 1 according to the embodiment. Firstly, as shown in FIG. 4, a solder paste 6 is formed on a plurality of electrodes 23 provided inside the first region 21a of the first face 21 of the substrate 2. The plurality of electrodes 23, for example, include the electrode 23 used for a transmission and a reception of a signal between the semiconductor part 3 and another circuit (for example, a memory controller) disposed on the substrate 2. Also, the plurality of electrodes 23, for example, include the electrode 23 connected to a power supply line (not shown) provided in an interior of the substrate 2. Also, the plurality of electrodes 23, for example, include the electrode 23 connected to a ground line (not shown) provided in the interior of the substrate 2. In FIG. 4, a via V connected to one electrode 23 and a wiring W connected to the via V are shown as representative of a structure inside the substrate 2.

When forming the solder paste 6 on the electrode 23 on the first region 21a, the solder paste 6 is also formed on the second region 21b. In the example shown in FIG. 4, the wiring W is not provided in the second region 21b. Also, a pad 230 is provided on the second region 21b. The pad 230 contains, for example, copper. The pad 230 can also be called a metal film or a dummy electrode. The solder paste 6 on the second region 21b is formed on a surface of the substrate 2 (that is, a surface of an insulating layer) across the pad 230. Because the solder paste 6 on the first region 21a and the solder paste 6 on the second region 21b are formed simultaneously, the semiconductor part 3 and the additional part 4 can be mounted efficiently. Also, because the pad 230 is provided on the second region 21b, which does not coincide with the wiring W, a mechanical connection of the substrate 2 and the additional part 4 can be carried out appropriately, while avoiding an electrical connection of the substrate 2 and the additional part 4.

FIG. 5 is a sectional view, continuing from FIG. 4, showing a method of manufacturing the semiconductor device 1 according to the embodiment. After forming the solder paste 6, the semiconductor part 3 is disposed on the solder paste 6 formed on the electrode 23, as shown in FIG. 5. Specifically, the semiconductor part 3 is disposed in such a way that a terminal (not shown) provided on a lower face (a face opposing the substrate 2) of the semiconductor part 3 comes into contact on the solder paste 6. At this time, the additional part 4 is disposed on the solder paste 6 formed on the pad 230.

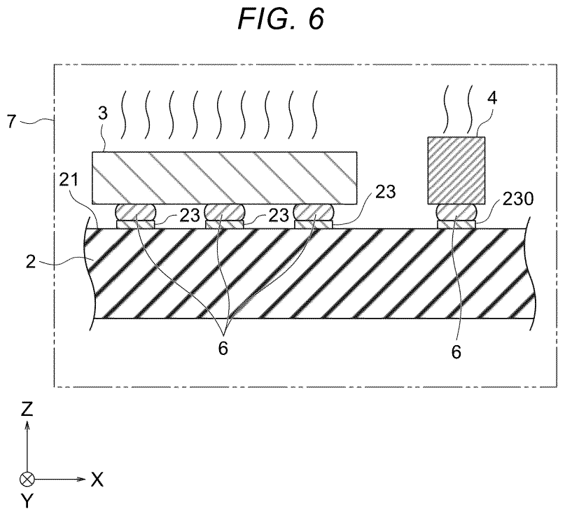

FIG. 6 is a sectional view, continuing from FIG. 5, showing a method of manufacturing the semiconductor device 1 according to the embodiment. After disposing the semiconductor part 3 and the additional part 4, the solder paste 6 is melted by being heated inside a reflow furnace 7, as shown in FIG. 6. Subsequently, the solder paste 6 is cured by stopping the heating. That is, a reflow soldering (that is, a reflow process) of the semiconductor part 3 and the additional part 4 is implemented. Because of this, the substrate 2 and the semiconductor part 3 are mechanically and electrically connected via the solder paste 6 on the electrode 23. Also, the substrate 2 and the additional part 4 are mechanically connected via the solder paste 6 on the pad 230, without being electrically connected.

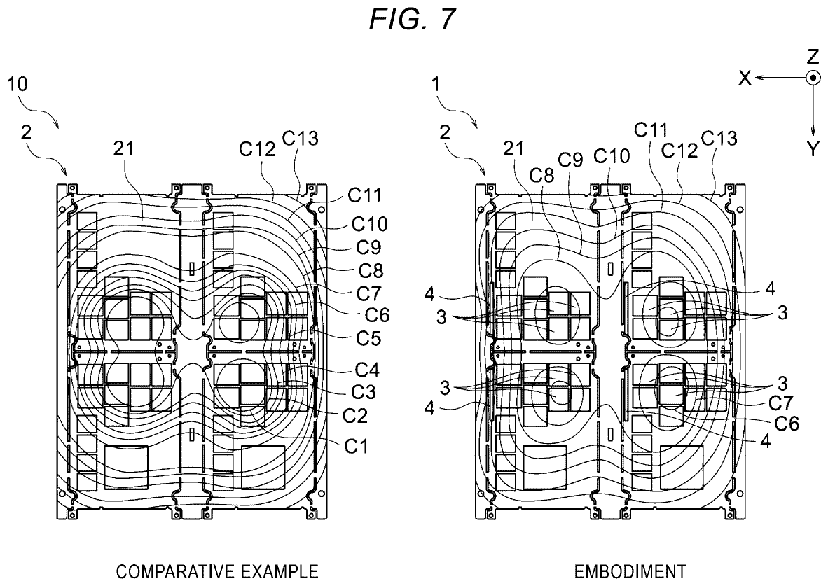

FIG. 7 is a plan view showing a result of simulating thermal warping (that is, deformation) of the substrate 2 of the semiconductor device 1 according to the embodiment. In FIG. 7, thermal warping of the semiconductor device 1 according to the embodiment, which is such that the additional part 4 is disposed in a vicinity of the center and an X direction end portion of the first face 21, is indicated by a contour diagram on the first face 21. Also, in FIG. 7, thermal warping of a semiconductor device 10 according to a comparative example, in which the additional part 4 is not disposed, is indicated by a contour diagram on the first face 21. In FIG. 7, contour lines C1 to C13 indicate, in order from C1, places in which an amount of displacement in the Z direction is large after the substrate 2 on which reflow soldering is implemented cools. That is, a region enclosed by the contour line C1 is a region in which the amount of displacement in the Z direction after reflow soldering is largest. Meanwhile, a region on an outer side of the contour line C13 is a region in which the amount of displacement in the Z direction after reflow soldering is smallest.

When the additional part 4 is not disposed on the substrate 2, as is the case with the semiconductor device 10 according to the comparative example, places in which the amount of displacement in the Z direction is large appear after the substrate 2 on which reflow soldering is implemented cools, as indicated by contour lines C1 to C5. That is, when the additional part 4 is not disposed on the substrate 2, considerable thermal warping of the substrate 2 occurs.

As opposed to this, because the semiconductor device 1 according to the embodiment has the additional part 4 disposed on the substrate 2, displacement in the Z direction is limited to the contour lines C6 to C13, which indicate smaller warping than the contour lines C1 to C5. Consequently, the semiconductor device 1 according to the embodiment is such that thermal warping of the substrate 2 is reduced more than is the case with the semiconductor device 10 according to the comparative example.

As heretofore described, the semiconductor device 1 according to the embodiment includes the substrate 2, which has the first linear expansion coefficient, at least one semiconductor part 3, and the additional part 4. The semiconductor part 3 is disposed on the first region 21a of the first face 21, and has the second linear expansion coefficient, which is smaller than the first linear expansion coefficient. The additional part 4 is disposed on the second region 21b of the first face 21, on which the semiconductor part 3 is not disposed, and has the third linear expansion coefficient, which is greater than the first linear expansion coefficient.

Herein, a case in which the additional part 4 is not disposed on the substrate 2 is such that when the substrate 2 cools after the semiconductor part 3 is mounted on the substrate 2 by soldering, considerable thermal warping of the substrate 2 occurs due to a difference in the linear expansion coefficients of the substrate 2, which has a large linear expansion coefficient, and the semiconductor part 3, which has a small linear expansion coefficient. Specifically, as the linear expansion coefficient of the semiconductor part 3 is smaller than the linear expansion coefficient of the substrate 2, an amount of contraction of the substrate 2 during the cooling process after reflow soldering is greater than an amount of contraction of the semiconductor part 3. Because of this, thermal warping such that the substrate 2 curves in the Z direction occurs in the substrate 2, as shown in the comparative example of FIG. 7.

As opposed to this, because the semiconductor device 1 according to the embodiment has the additional part 4, whose linear expansion coefficient is greater than that of the substrate 2, thermal warping (that is, distortion) can be caused to occur in a direction opposite to that of the thermal warping (distortion) that occurs due to the difference in the linear expansion coefficients of the semiconductor part 3 and the substrate 2. Because of this, thermal warping in mutually opposing directions can be sufficiently offset, meaning that thermal warping of the substrate 2 can be effectively reduced. As thermal warping of the substrate 2 can be reduced, mounting of another semiconductor part on the second face 22 of the substrate 2 can be carried out easily and appropriately. Also, as the additional part 4 is not a semiconductor part, a degree of freedom of layout is extensive in comparison with a case in which a semiconductor part is disposed. For example, the additional part 4 can also be disposed in a constricted space where a semiconductor part cannot be disposed.

Also, the semiconductor device 1 according to the embodiment is such that the additional part 4 is disposed in a vicinity of the center of the first face 21.

As the additional part 4 can be disposed in a vicinity of the center of the first face 21, whose amount of displacement in the Z direction of the substrate 2 is considerable, thermal warping of the substrate 2 can be more effectively reduced.

Also, the semiconductor device 1 according to the embodiment is such that the dimension of the additional part 4 in the X direction of the first face 21 is smaller than that of the semiconductor part 3.

Because of this, warping of the substrate 2 can be reduced, while making effective use of an empty constricted space on the substrate 2.

Also, the semiconductor device 1 according to the embodiment is such that the additional part 4 has a rod shape extending in the Y direction that intersects the X direction of the first face 21.

Because of this, warping of the substrate 2 can be effectively reduced by the additional part 4 of a simple configuration.

Also, the semiconductor device 1 according to the embodiment is such that the additional part 4 extends in the Y direction to a length such as to oppose two or more semiconductor parts 3 when seen from the X direction.

Because of this, an area of the additional part 4 can be increased as much as possible, meaning that warping of the substrate 2 can be more effectively reduced.

Also, the semiconductor device 1 according to the embodiment is such that the additional part 4 is configured of metal.

As the additional part 4 can be configured of metal, which has excellent heat resistance, reflow soldering can be carried out appropriately.

Also, the semiconductor device 1 according to the embodiment is such that the metal contains aluminum.

Because of this, the additional part 4 can be provided at low cost.

Also, the semiconductor device 1 according to the embodiment is such that the semiconductor part 3 is mechanically and electrically connected to the substrate 2 via the solder paste 6 disposed on the first region 21a. Also, the additional part 4 is mechanically connected to the substrate 2 across the solder paste 6 disposed on the second region 21b, without being electrically connected.

Because of this, the additional part 4 can be mounted using the solder paste 6 used in mounting the semiconductor part 3, meaning that warping of the substrate 2 can be reduced at low cost.

Also, according to the embodiment, disposition of the semiconductor part 3 and disposition of the additional part 4 are carried out simultaneously.

Because of this, the semiconductor part 3 and the additional part 4 can be efficiently mounted, in addition to which warping of the substrate 2 can be effectively reduced.

Also, according to the embodiment, disposition of the semiconductor part 3 and disposition of the additional part 4 are carried out using reflow soldering.

Because of this, the semiconductor part 3 and the additional part 4 can be mounted with high accuracy.

A plurality of modifications shown below can be applied to the embodiment.

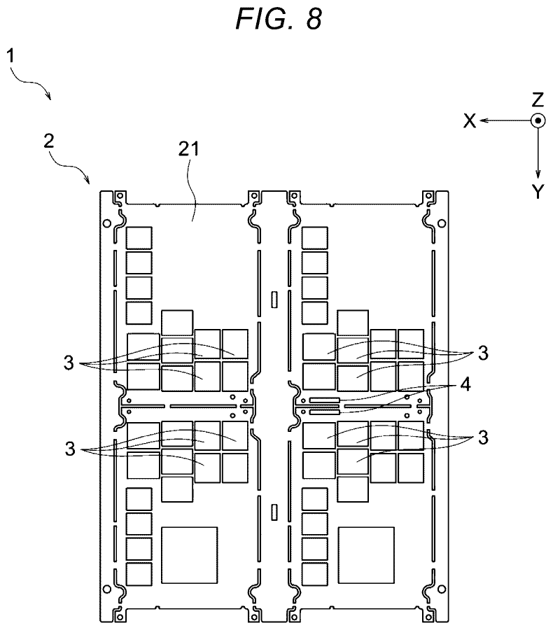

FIG. 8 is a plan view showing the semiconductor device 1 according to a first modification of the embodiment. The example described thus far is such that the additional part 4 has a rod shape extending in the Y direction. As opposed to this, the additional part 4 may have a rod shape extending in the X direction, as shown in FIG. 8. A dimension of the additional part 4 in the X direction of the first face 21 is greater than that of the semiconductor part 3. Because of this, the degree of freedom in laying out the additional part 4 can be further increased.

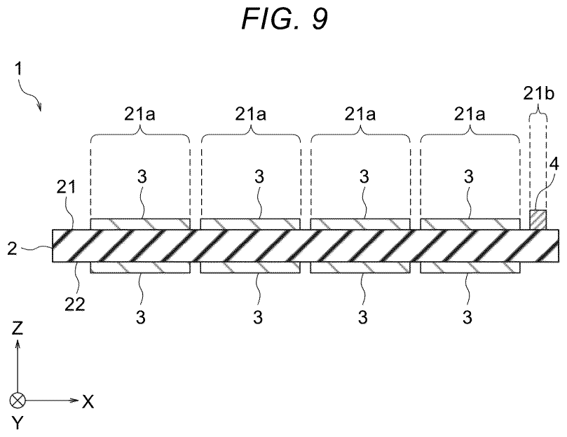

FIG. 9 is a sectional view showing the semiconductor device 1 according to a second modification of the embodiment. In the example shown in FIG. 9, a second semiconductor part 3 is disposed on the second face 22. In the same way as the semiconductor part 3 on the first face 21, the second semiconductor part 3 is mounted on the second face 22 using reflow soldering. In the example shown in FIG. 9, the second semiconductor part 3 is disposed in a position immediately opposite the semiconductor part 3 on the first face 21 in the Z direction. As warping of the substrate 2 is reduced by the additional part 4 disposed on the first face 21, the second semiconductor part 3 can be appropriately mounted on the second face 22.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a substrate that has a first face and a second face on a side opposite to that of the first face, and has a first linear expansion coefficient;
at least one semiconductor part that is disposed on a first region of the first face and has a second linear expansion coefficient that is smaller than the first linear expansion coefficient; and
a non-semiconductor part that is disposed on a second region of the first face, on which no semiconductor part is disposed, and has a third linear expansion coefficient that is greater than the first linear expansion coefficient.

2. The semiconductor device according to claim 1, wherein the non-semiconductor part is disposed in a vicinity of a center of the first face.

3. The semiconductor device according to claim 1, wherein a dimension of the non-semiconductor part in a first direction along the first face is smaller than that of the at least one semiconductor part.

4. The semiconductor device according to claim 3, wherein the non-semiconductor part has a rod shape extending along the first face in a second direction that intersects the first direction.

5. The semiconductor device according to claim 4, wherein the at least one semiconductor part includes two or more semiconductor parts arranged in the second direction, and
the non-semiconductor part extends in the second direction to a length so as to oppose the two or more semiconductor parts when seen from the first direction.

6. The semiconductor device according to claim 1, wherein the non-semiconductor part is made of metal.

7. The semiconductor device according to claim 6, wherein the metal is aluminum.

8. The semiconductor device according to claim 1, wherein
the substrate has wiring, and
the at least one semiconductor part is electrically connected to the wiring, and the non-semiconductor part is not electrically connected to the wiring.

9. The semiconductor device according to claim 1, further comprising at least one second semiconductor part disposed on the second face.

10. A semiconductor device, comprising:
a substrate that has a first face and a second face on a side opposite to that of the first face;
a plurality of first semiconductor chips mounted on the first face of the substrate and arranged on a first side of a center line that extends in a first direction through a center of the first face, wherein at least two of the first semiconductor chips are aligned in a second direction that is perpendicular to the first direction;
a plurality of second semiconductor chips mounted on the first face of the substrate and arranged on a second side of the center line, wherein at least two of the second semiconductor chips are aligned in the second direction;
a first non-semiconductor part mounted on the first face of the substrate on the first side of the center line and extending in the second direction; and
a second non-semiconductor part mounted on the first face of the substrate on the second side of the center line and extending in the second direction,
wherein a linear expansion coefficient of the first non-semiconductor part and a linear expansion coefficient of the second non-semiconductor part are each greater than a linear expansion coefficient of the substrate, and the linear expansion coefficient of the substrate is greater than a linear expansion coefficient of each of the first and second semiconductor chips.

11. The semiconductor device according to claim 10, wherein a dimension of the first non-semiconductor part in the first direction and a dimension of the second non-semiconductor part in the first direction is smaller than that of each of the first and second semiconductor chips.

12. The semiconductor device according to claim 11, wherein a height of the first non-semiconductor part above the substrate and a height of the second non-semiconductor part above the substrate is greater than that of each of the first and second semiconductor chips.

13. The semiconductor device according to claim 12, wherein
the first non-semiconductor part extends in the second direction to a length so as to face the at least two first semiconductor chips aligned in the second direction, in the first direction, and
the second non-semiconductor part extends in the second direction to a length so as to face the at least two second semiconductor chips aligned in the second direction, in the first direction.

14. The semiconductor device according to claim 13, wherein each of the first and second semiconductor chips and the first and second non-semiconductor parts is mounted on the first face of the substrate through a corresponding electrode and fixed to the corresponding electrode through a solder paste.

15. The semiconductor device according to claim 14, wherein
the substrate has wiring, and
the first and second semiconductor chips are electrically connected to the wiring, and the first and second non-semiconductor parts are not electrically connected to the wiring.

16. The semiconductor device according to claim 10, wherein the first non-semiconductor part and the second non-semiconductor part are each made of metal.

17. A semiconductor device manufacturing method, comprising:
mounting at least one semiconductor part on a first face of a substrate; and
mounting a non-semiconductor part on the first face of the substrate,
wherein a linear expansion coefficient of the non-semiconductor part is greater than a linear expansion coefficient of the substrate, and the linear expansion coefficient of the substrate is greater than a linear expansion coefficient of the at least one semiconductor part.

18. The semiconductor device manufacturing method according to claim 17, wherein the at least one semiconductor part and the non-semiconductor part are mounted simultaneously.

19. The semiconductor device manufacturing method according to claim 18, wherein the at least one semiconductor part and the non-semiconductor part are mounted using reflow soldering.

20. The semiconductor device manufacturing method according to claim 17, further comprising:
mounting at least one second semiconductor part on a second face of the substrate that is opposite to the first face, after mounting the at least one semiconductor part and the non-semiconductor part on the first face.
